(19) United States
(12) Patent Application Publication
(10) Pub. No.: US 2026/0196917 A1
(43) Pub. Date: Jul. 9, 2026

(54) VOLTAGE MODE CONTROL FOR MULTI-LEVEL POWER CONVERTER

(71) Applicant: pSemi Corporation, San Diego, CA (US)

(72) Inventors: Daniel Zhou, Princeton, NJ (US); Gregory Szczeszynski, Nashua, NH (US)

(21) Appl. No.: 19/553,089

(22) Filed: Feb. 27, 2026

Related U.S. Application Data
(63) Continuation of application No. PCT/US2024/041801, filed on Aug. 9, 2024.
(60) Provisional application No. 63/579,889, filed on Aug. 31, 2023.
(60) Provisional application No. 63/619,088, filed on Jan. 9, 2024.

(51) Int. Cl. H02M 1/00; H02M 1/15; H03K 7/08

(52) U.S. Cl. CPC H02M 1/0016; H02M 1/0012; H02M 1/15; H03K 7/08

(57) ABSTRACT

Circuits and methods for controlling generation of PWM clocking signals for an M-level converter cell such that regulation cannot be lost when transitioning across dead zones and large output current and voltage spikes are avoided or substantially reduced. Embodiments utilize a voltage mode control system in which a 3-state PWM duty cycle is linearly related to a compensation voltage V_{COMP} that can be sensed and manipulated directly. When shifting between zones as sensed from V_{COMP}, embodiments alternate the duty cycles of pairs of adjacent PWM cycles to achieve a smooth transition. Within a dead zone, a first cycle of a pair of adjacent PWM cycles has a 2-state duty cycle with an upper voltage that increases in duration during the transition sequence, and a second cycle of the pair of adjacent PWM cycles has a 2-state duty cycle with a lower voltage that decreases in duration during the transition sequence.

### CROSS-REFERENCE TO RELATED APPLICATIONS

This application is a continuation of International Patent Application No. PCT/US2024/041801 filed Aug. 9, 2024 and entitled VOLTAGE MODE CONTROL FOR MULTI-LEVEL POWER CONVERTER,” which claims priority to and the benefit of U.S. Provisional Patent Application No. 63/619,088 filed on Jan. 9, 2024, and to U.S. Provisional Patent Application No. 63/579,889 filed on Aug. 31, 2023, all of which are incorporated herein by reference in their entirety.

### BACKGROUND

### (1) Technical Field

This invention relates to electronic circuits, and more particularly to multi-level power converters.

### (2) Background

Many electronic devices, particularly mobile computing and/or communication products and components (e.g., notebook computers, ultra-book computers, and tablet devices) may be powered from multiple sources, including batteries, solar cells, and rectified AC sources (e.g., a USB charger or wireless charging circuitry). It is common to use a direct current power converter to generate a lower or higher voltage from a selected power source, such as a rectified AC source, to both power an electronic device and to charge a battery internal to the electronic device.

Power converters which generate a lower output voltage level from a higher input voltage power source are commonly known as buck converters, so-called because the output voltage V_{OUT} is less than the input voltage V_{IN}, and hence the converter is “bucking” the input voltage. Power converters which generate a higher output voltage level from a lower input voltage power source are commonly known as boost converters, because V_{OUT} is greater than V_{IN}. Some power converters may be either a buck converter or a boost converter depending on which terminals are used for input and output. Some power converters may provide an inverted output.

FIG. 1 is a block diagram of a prior art power converter 100. In the illustrated example, the power converter 100 includes a multi-level (M-level) converter cell 102 and a controller 104. The M-level converter cell 102 is configured to receive an input voltage V_{IN} from a voltage source 106 (e.g., a rectified AC source) across terminals V1+, V1− (common), and transform the input voltage V_{IN} into an output voltage V_{OUT} across terminals V2+, V2− (common). The output voltage V_{OUT} is generally coupled across an output capacitor C_{OUT}, across which may be connected a load 108, such as a battery and/or an electronic device.

The controller 104 receives a set of input signals and produces a set of output signals. Some of these input signals arrive along a signal path 110 connected to the converter cell 102. Some input signals carry information indicative of the operational state of the converter cell 102. The controller 104 generally also receives one or more external input/output signals I/O that may be analog, digital (encoded or direct signal lines), or a combination of both, and a clock/timing signal CLK. Based upon the received input signals, the controller 104 provides a set of control signals, including clocking signals φ₁ . . . φₙ, back to the converter cell 102 on the signal path 110 that control the internal components of the converter cell 102 (e.g., internal power switches, such as FETs, especially MOSFETs) to cause the converter cell 102 to convert V_{IN} to V_{OUT}. Each power switch will generally have a level shifter and driver circuit coupled to a control input (e.g., the gate of a FET implementing the power switch) so as to enable switching the power switch ON or OFF based on a logic-level clock and/or control signal. In some embodiments, an auxiliary circuit (not shown) may provide various signals to the controller 104 (and optionally directly to the converter cell 102), such as the clock signal CLK, the input/output signals I/O, as well as various voltages, such as a general system supply voltage V_{DD} and at least one transistor bias voltage V_{BIAS}.

One type of M-level converter cell 102 includes charge transfer capacitors as energy storage elements coupled by controlled power switches so as to transfer charge from V_{IN} to V_{OUT}. Such charge transfer capacitors are commonly known as “fly capacitors” or “pump capacitors”. Every time a fly capacitor is used (i.e., not bypassed), electrical energy flowing through that fly capacitor generally will either charge it or discharge it. For example, FIG. 2 is a schematic diagram of a prior art 3-level converter cell 200. Power field-effect transistors (FETs) M0-M3 have their conduction channels (drain-to-source) coupled in series between an input voltage V_{IN} and a reference potential (e.g., circuit ground). Clocking signals φ₀-φ₃ from a pulse-width modulation (PWM) generator circuit 202 applied (directly or indirectly) to respective power FETs M0-M3 control the ON (conducting) or OFF (blocking) state of the power FETs (note that level shifting, driver, and control circuitry has been omitted for the sake of simplicity). The PWM generator circuit 202 produces the clocking signals φ₀-φ₃ based in part on the output voltage V_{OUT} of the converter cell 102 and a clock waveform CLK that may be provided, for example, by the controller 104 of FIG. 1.

An energy-storage fly capacitor C_{F1} is coupled between a high-side node HS1 (between power FETs M0 and M1) and a low-side node LS1 (between power FETs M2 and M3). An energy-storage inductor L is coupled between a load 108 and a node Lx which separates the high-side power FETs M0, M1 from the low-side power FETs M2, M3. An output capacitor C_{OUT} is coupled between the inductor L and a reference potential. The fly capacitor C_{F1}, the inductor L, and the output capacitor C_{OUT} are generally external components with respect to the controller 104 and the power FETs of the converter cell 102.

The 3-level converter cell 200 enables generation of three instantaneous voltage levels at node Lx during normal operation, depending on the ON-OFF state of power FETs M0-M3: V_{IN}, V_{IN}/2, or 0V. For example, if V_{IN}=5V, then during normal operation Lx can have the values 5V, 2.5V, or 0V. Using these values as one example, the average voltage values at V_{OUT} can be in one of two zones: in Zone 1, V_{OUT} can theoretically range from 0V to 2.5V (i.e., V_{IN}/2) by alternating between 0V and 2.5V at node Lx, and in Zone 2, V_{OUT} can theoretically range from 2.5V to 5.V (i.e., V_{IN}) by alternating between 2.5V and 5V at node Lx. However, the inductor L in FIG. 2 needs a minimum voltage drop to quickly charge/discharge the inductor L in order not to impact loop response. If V_{OUT} approaches a voltage close to or at the boundary between adjacent voltage levels (e.g., the boundary at V_{IN}/2) of the converter circuit, the converter cell 200 reaches a “dead zone” where there is not enough voltage drop across the inductor L to meet transient responses. Stated another way, the duty cycle d of the power FETs M0-M3 cannot be at or close to 100% (when approaching an upper zone from a lower zone, such as transitioning from Zone 1 to Zone 2) or at or close to 0% (when approaching a lower zone from an upper zone, such as transitioning from Zone 2 to Zone 1).

For example, FIG. 3 is a graph 300 of the available voltage levels V_{Lx} at node Lx for a 3-level converter cell. A margin 302 is added around intra-boundary voltage level transitions (V_{IN}/2 in this example) to define a dead zone in which the duty cycle d of PWM clocking signals is constrained such that a minimum/maximum pulse width is maintained (e.g., 5% to 95% or 10% to 90%). Accordingly, the duty cycle d cannot be set to values outside the defined min/max range. As another example, FIG. 4 is a graph 400 of the available voltage levels V_{Lx} at node Lx for a 4-level converter cell. A first margin 402 is added around a lower intra-boundary voltage level transition (V_{IN}*⅓) and a second margin 404 is added around an upper intra-boundary voltage level transition (V_{IN}*⅔) to define respective dead zones.

One design challenge of an M-level converter cell involves controlling generation of PWM clocking signals such that regulation cannot be lost when transitioning across dead zones and output current and voltage large spikes are avoided or substantially reduced, all while achieving high efficiency. The present invention provides an effective, efficient, and compact circuit that meets this design challenge.

### SUMMARY

The present invention encompasses circuits and methods for controlling generation of PWM clocking signals for an M-level converter cell such that regulation cannot be lost when transitioning across dead zones and large output current and voltage spikes are avoided or substantially reduced, all while achieving high efficiency. Embodiments of the present invention utilize a voltage mode control system in which a PWM duty cycle d is linearly related to a compensation voltage V_{COMP} that is based in part on the output voltage V_{OUT}. An advantage of this approach is that V_{COMP} can be sensed to determine zones (including dead zones) and manipulated directly to produce suitable PWM duty cycles d in such zones. Taking advantage of the fact that the PWM duty cycle d is linearly related to V_{COMP} in a voltage mode control system, embodiments of the present invention can determine when a dead zone is being entered and, when shifting between zones, can beneficially alternate the duty cycles of pairs of adjacent PWM cycles to achieve a smooth transition using a “duty cycle level shifter” circuit and associated method.

One aspect of the present invention includes PWM generator for a multi-level converter cell, configured to transition from a first zone of operation to a second zone of operation through a dead zone of operation, and to generate in the dead zone of operation a PWM cycle having a 3-state duty cycle. The first state of the 3-state duty cycle comprises a discharging voltage state D, the second state comprises a neutral voltage state N, and the third state comprises a charging voltage state C, wherein a voltage level of the neutral voltage state N is between a voltage level of the discharging voltage state D and a voltage level of the charging voltage state C.

Embodiments include a voltage mode control system for a multi-level converter cell, where the voltage mode control system includes an error amplifier having a first input coupled to a source of a target voltage signal, a second input coupled to a signal representing an output voltage of the multi-level converter cell, and a compensation signal output; a voltage ramp generator configured to output a ramped voltage signal having a selected frequency; a flag circuit coupled to the ramped voltage signal and configured to output a dead zone flag signal at one-half of the selected frequency of the ramped voltage signal; a comparator having a first input coupled to the voltage ramp generator, a second input, and an output for pulse-width modulated (PWM) cycles to be provided to the multi-level converter cell; and a duty cycle level shifter circuit coupled to the compensation signal output of the error amplifier, the duty cycle level shifter circuit configured to provide a modified compensation signal to the second input of the comparator that alternates duty cycles of pairs of adjacent PWM cycles within a dead zone of operation of the multi-level converter cell to achieve a smooth transition sequence from a first zone of operation into the dead zone of operation and from the dead zone of operation to a second zone of operation.

The details of one or more embodiments of the invention are set forth in the accompanying drawings and the description below. Other features, objects, and advantages of the invention should be apparent from the description and drawings, and from the claims.

### DESCRIPTION OF THE DRAWINGS

FIG. 1 is a block diagram of a prior art power converter.

FIG. 2 is a schematic diagram of a prior art 3-level converter cell.

FIG. 3 is a graph of the available voltage levels V_{Lx} at node Lx for a 3-level converter cell.

FIG. 4 is a graph of the available voltage levels V_{Lx} at node Lx for a 4-level converter cell.

FIG. 5A is a graph of voltage levels V_{Lx} at node Lx versus time for a 4-level converter cell during a transition from Zone 1 to Zone 2 through a dead zone around V_{IN}/3.

FIG. 5B is a first graph showing ripple current through node Lx as function of time.

FIG. 5C is a second graph showing ripple current through node Lx as function of time.

FIG. 5D is a double graph of voltage levels V_{Lx} at node Lx versus time and ripple current through the inductor L versus time for a 4-level converter cell, showing a single 3-state PWM cycle in a dead zone around V_{IN}/3.

FIG. 5E is a graph of voltage levels V_{Lx} at node Lx versus time for a 4-level converter cell, showing a single 3-state PWM cycle in a dead zone around V_{IN}/3.

FIG. 6 is a set of related subgraphs showing various characteristics of a voltage mode PWM generator circuit as a function of time.

FIG. 7 is a set of related subgraphs showing a sequence of dead zone characteristics of an improved voltage mode control system as a function of time.

FIGS. 8A and 8B are block diagrams showing one embodiment of a voltage mode PWM generator circuit that includes a duty cycle level shifter circuit for a 4-level converter cell.

FIG. 9 is a block diagram of one embodiment of control circuitry for an M-level converter cell coupled to an output block comprising an inductor L and an output capacitor C_{OUT}.

FIG. 10 is a top plan view of a substrate that may be, for example, a printed circuit board or chip module substrate (e.g., a thin-film tile).

FIG. 11 is a process flow chart showing a method of transitioning from a first zone of operation of a PWM generator to a second zone of operation of the PWM generator through a dead zone of operation.

FIG. 12 is a process flow chart showing a method of smoothly transitioning from a first zone of operation of a PWM generator to a second zone of operation of the PWM generator through a dead zone of operation.

FIG. 13 is a process flow chart showing a method of smoothly transitioning from a first zone of operation of a PWM generator for a multi-level converter to a second zone of operation of the PWM generator through a dead zone of operation.

Like reference numbers and designations in the various drawings indicate like elements unless the context requires otherwise.

### DETAILED DESCRIPTION

The present invention encompasses circuits and methods for controlling generation of PWM clocking signals for an M-level converter cell such that regulation cannot be lost when transitioning across dead zones and large output current and voltage spikes are avoided or substantially reduced, all while achieving high efficiency. Embodiments of the present invention utilize a voltage mode control system in which a PWM duty cycle d is linearly related to a compensation voltage V_{COMP} that is based in part on V_{OUT}. An advantage of this approach is that V_{COMP} can be sensed to determine zones (including dead zones) and manipulated directly to produce suitable PWM duty cycles d in such zones. Taking advantage of the fact that the PWM duty cycle d is linearly related to V_{COMP} in a voltage mode control system, embodiments of the present invention can determine when a dead zone is being entered and, when shifting between zones, can beneficially alternate the duty cycles of pairs of adjacent PWM cycles to achieve a smooth transition using a “duty cycle level shifter” circuit and associated method.

In order to achieve voltages at node Lx that have average V_{Lx} values within defined dead zones, one approach is to create operational hybrid PWM cycles which utilize 3-state duty cycles. By using a “middle” or “neutral” state, the ripple current in the inductor L may be increased sufficiently to overcome the dead zone issue by a controlled amount in order to minimize losses. Such an approach differs from solutions that jump between only two levels—a lower voltage level and a non-adjacent higher voltage level—to increase the voltage drop across the inductor L, which significantly increases the ripple current in the inductor L and thus increases losses in the system.

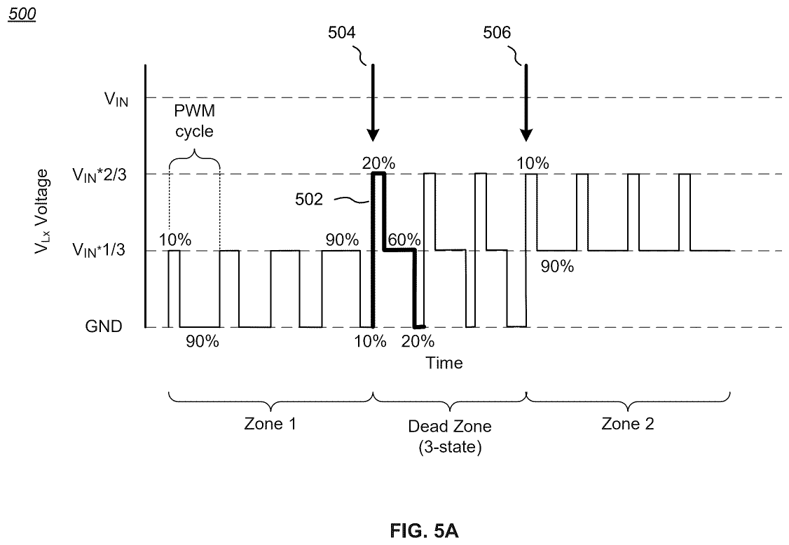

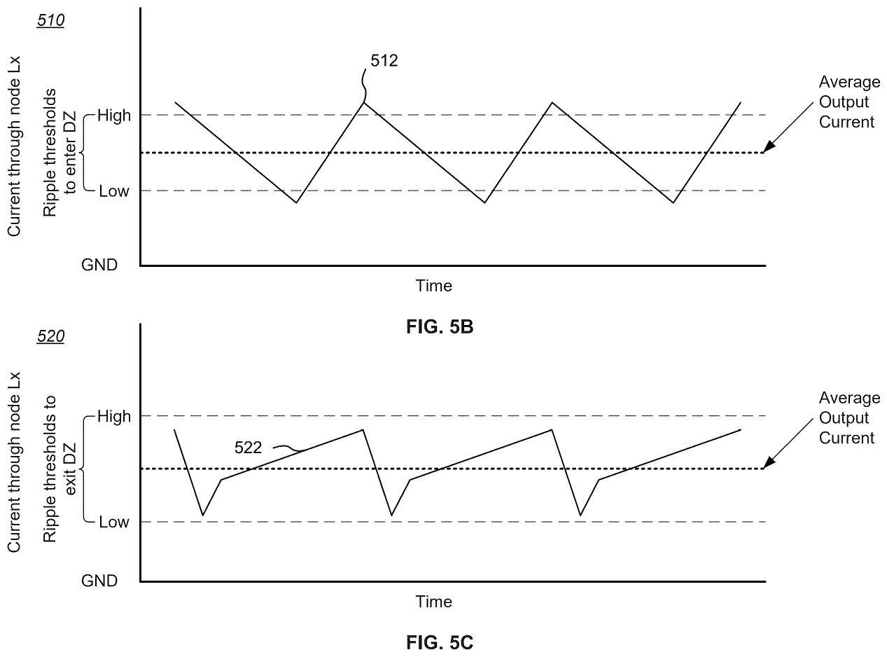

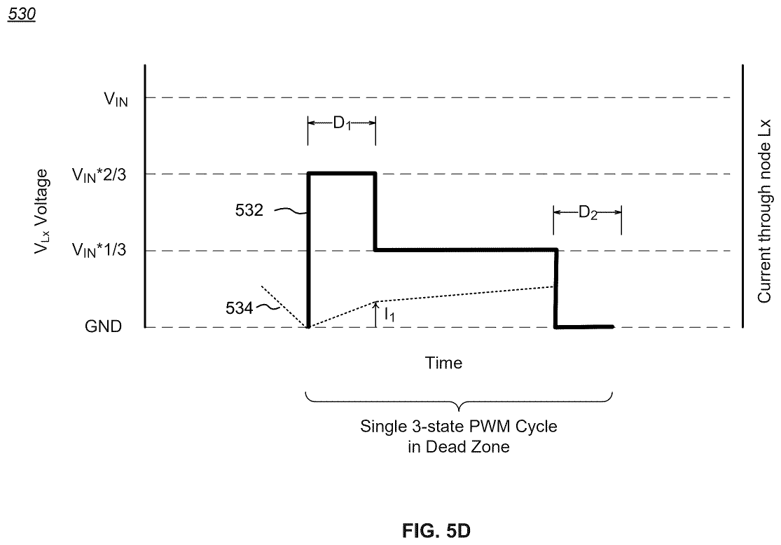

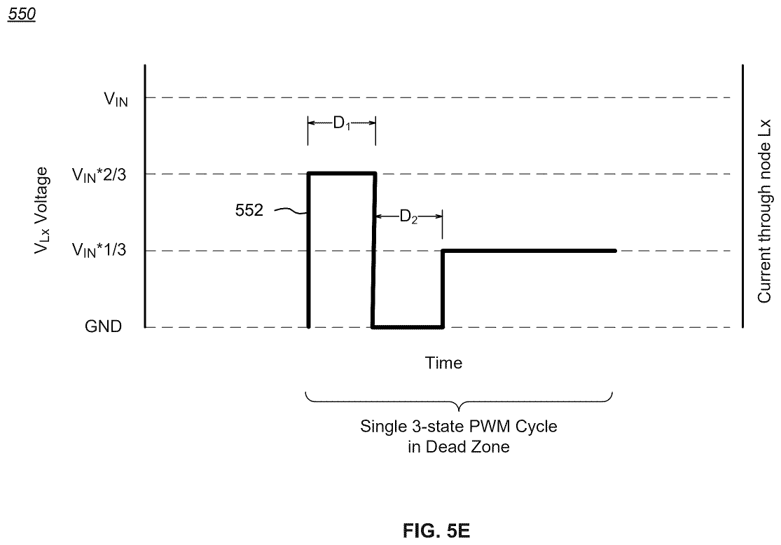

For example, FIG. 5A is a graph 500 of voltage levels V_{Lx} at node Lx versus time for a 4-level converter cell during a transition from Zone 1 to Zone 2 through a dead zone around V_{IN}/3. The duty cycle d for a 2-state PWM cycle is the ratio of time the PWM waveform is at the highest voltage within a zone relative to the duration of the PWM cycle. In FIG. 5A, the duty cycle d of the PWM cycles in Zone 1 increases over time from 10% to 90% as the average voltage <V_{Lx}> at node Lx is ramped up. Thus, in this example, just before transitioning out of Zone 1 to the dead zone, the PWM cycles in Zone 1 spend 90% of the cycle time at V_{IN}/3 and 10% of the cycle time at 0V (ground); the average voltage <V_{Lx}> at node Lx would be 0.9*V_{IN}/3.

In accordance with the present invention, within a dead zone (e.g., bracketing V_{IN}/3), a hybrid PWM scheme is used in which the voltage at node Lx is switched between more than two states. For example, bolded waveform 502 represents a 3-state duty cycle in which the voltage applied to node Lx is V_{IN}*⅔ for 20% of the cycle time (a fast charging state), then V_{IN}*⅓ for 60% of the cycle time (a slow charging or discharging state, depending on the then-current charge at node Lx), and then 0V (GND) for 20% of the cycle time (a discharging state). With these example values, during the 3-state duty cycle, the average voltage <V_{Lx}> at node Lx will be 1.0*V_{IN}/3 compared to the last average voltage in Zone 1 of 0.9*V_{IN}/3. A next transition is from the dead zone to Zone 2, in which 2-state PWM cycles are again used, with a duty cycle d of 10%; the average voltage <V_{Lx}> at node Lx will be 0.1*V_{IN}*⅔+0.9*V_{IN}*⅓, or 1.1*V_{IN}/3 compared to the last average voltage of 1.0*V_{IN}/3 in the dead zone.

Thus, after determining that a voltage at node Lx is to be set for a dead zone, in the illustrated example, a PWM cycle moves from a low discharging state to a non-adjacent higher charging state (skipping an intermediate neutral state), then back from the higher charging state to the neutral state, then back to the low discharging state. However, the order of state moves may be changed in some embodiments. For example, in alternative embodiments, if the states are represented by codes D=discharging state, C=charging state, and N=neutral state, then the PWM cycle may be represented by the sequences DCN, DNC, CDN, CND, NCD, or NDC. In any case, the use of the neutral state results in a much slower charging or discharging rate for the inductor L at node Lx.

A controller 104 for an M-level converter cell 102 should be configured to determine when a 3-state PWM duty cycle should be used. A number of different methods may be used for beginning and ending 3-state PWM duty cycles. For example, one open-loop feed-forward method may use 3-state PWM duty cycles when the output voltage V_{OUT} or the PWM duty cycle are within a pre-defined range arbitrarily determined to require dead zone operation, switching back to regular 2-state operation when V_{OUT} or the PWM duty cycle are outside the pre-defined range. Alternatively, the dead zone range triggering use of 3-state PWM duty cycles may be a fixed voltage difference (delta) at node Lx from one or more ideal multi-level voltage levels (e.g., V_{IN}*⅔ or V_{IN}/3 for a 4-level converter cell), based on a minimum or maximum PWM duty cycle. Alternatively, the dead zone range triggering use of 3-state PWM duty cycles may be based on a percentage of V_{IN}, or scaled based on some function of V_{IN} voltage, output voltage V_{OUT}, temperature, inductor L parameters, or load current. In addition, the controller 104 may respond to an external signal indicating a transient is coming or has passed may also be used to begin and end 3-state PWM duty cycles.

Closed-loop methods also may be used to begin and end 3-state PWM duty cycles. For example, a controller 104 may be configured to use 3-state PWM duty cycles while the current ripple through the inductor L is less than a first pre-defined threshold, switching back to regular 2-state operation when the current ripple is greater than a second pre-defined threshold (in some embodiments, the first and second pre-defined thresholds may be equal). For example, FIG. 5B is a first graph 510 showing ripple current (graph line 512) through node Lx as function of time. The presence of the ripple current 512 outside the Low/High range may be used to trigger 3-state PWM duty cycles.

Exiting trigger 3-state PWM duty cycles may use a different Low/High range to provide hysteresis. For example, FIG. 5C is a second graph 520 showing ripple current (graph line 522) through node Lx as function of time. While the ripple current 522 remains inside the Low/High range—which is wider than the Low/High range of FIG. 5B—use of 3-state PWM duty cycles may continue. When the ripple current 522 is outside the wider Low/High range the system may switch back to regular 2-state operation.

The closed-loop pre-defined ripple current threshold may be set based on similar considerations as for open-loop feed-forward methods: PWM duty cycle, temperature, fixed setpoints, inductor L parameters, output voltage V_{OUT}, input voltage V_{IN}, etc. In addition, the controller 104 may respond to an external signal indicating a transient is coming or has passed may also be used to begin and end 3-state PWM duty cycles when using closed-looped control.

The duration of the non-adjacent charging state and/or the discharging state relative to the neutral state may also be set by either open-loop or closed loop techniques. For example, FIG. 5D is a double graph 530 of voltage levels V_{Lx} at node Lx versus time and ripple current through the inductor L versus time for a 4-level converter cell, showing a single 3-state PWM cycle (graph line 532) in a dead zone around V_{IN}/3. In this example, the PWM cycle is represented by the sequence CND and the “C” charging state has a duration of D₁. If the PWM cycle is represented by the sequence DNC (i.e., if the timing of graph line 532 is reversed), the “D” discharging state has a duration of D₂.

As another example, FIG. 5E is a graph 550 of voltage levels V_{Lx} at node Lx versus time for a 4-level converter cell, showing a single 3-state PWM cycle (graph line 552) in a dead zone around V_{IN}/3. In this example, the PWM cycle is represented by the sequence CDN, with the “C” charging state having duration of D₁ and the “D” discharging state having a duration of D₂.

Using open-loop feed-forward methods, the duration of D₁ or D₂ may be pre-defined or may vary with output voltage V_{OUT}, input voltage V_{IN}, inductor L parameters, temperature, load current, etc. Using closed-loop ripple current control, the ripple current through the inductor L may be monitored and the duration of D₁ or D₂ may be adjusted to maintain a desired ripple current level. With this method, when either the charging state or the discharging state begins, the change in the ripple current is monitored and when a pre-defined threshold is met, the controller 104 switches the PWM cycle to the neutral state.

For example, referring to FIG. 5D, graph line 534 represents the ripple current through the inductor L. In the illustrated example, upon entering a dead zone, a 3-state PWM cycle begins with a charging state of duration D₁. After commencement of the charging state (V_{IN}*⅔ in this example), charging of node Lx proceeds rapidly until the ripple current 534 reaches a pre-defined threshold I₁, when the controller 104 switches the PWM cycle to the neutral state (V_{IN}*⅓ in this example) and charging proceeds more slowly. Alternatively, the total ripple current (including neutral state) is monitored and the D₁ duration is adjusted based on previous measured levels. The pre-defined threshold level of I₁ may vary with output voltage V_{OUT}, input voltage V_{IN}, inductor L parameters, temperature, load current, etc.

In some embodiments, such as the example shown in FIG. 5E, it may be useful to set the duration of charging (D₁) and discharging (D₂) such that the sum of the durations is a selected constant K: D₁+D₂=K.

In some embodiments, transitions between normal operating zones and an intervening dead zone in which 3-state PWM cycles are used may result in undesirable voltage spikes. For example, referring back to FIG. 5A, during the 3-state duty cycle, the average voltage <V_{Lx}> at node Lx will be 1.0*V_{IN}/3, resulting in a relatively abrupt change in the average voltage <V_{Lx}> at node Lx compared to the last average voltage in Zone 1 of 0.9*V_{IN}/3; arrow 504 indicates that a large spike may result at the indicated transition point. For the next transition from the dead zone to Zone 2, in which 2-state PWM cycles are again used with a duty cycle d of 10%, the average voltage <V_{Lx}> at node Lx will be 1.1*V_{IN}/3, resulting in a relatively abrupt change in average voltage <V_{Lx}> at node Lx compared to the last average voltage of 1.0*V_{IN}/3 in the dead zone; arrow 506 indicates that a large spike may result at the indicated transition point.

Accordingly, a control system design problem for some embodiments is detecting when a converter cell transitions into and out of a dead zone and generating 3-state PWM cycles while in a dead zone that do not cause the inductor L current and/or the output voltage V_{OUT} to spike.

A conventional current mode control system relies upon external measurement of the voltage V_{OUT} after the inductor L (eventually converted to a voltage compensation signal V_{COMP}) to determine if an M-level converter cell is operating within a dead zone. However, in a conventional current mode control system feedback loop, generation of a compensation voltage V_{COMP} cannot be used to determine duty cycles because the V_{COMP} value changes with the current I_{L} to the load. In other words, PWM duty cycle d is not linearly related to V_{COMP} in a conventional current mode control system. Further, such a control system is susceptible to errors due to parasitic impedances. For example, the inductor L (an external component generally chosen by a customer) may have a large equivalent series resistance (ESR) which generally would be unknown to the current mode control system designer. If the ESR is so large that the average voltage <V_{L}> across the inductor L is essentially zero (meaning that I_{L} is essentially zero) without switching to the next highest zone, then regulation can be lost as the current mode control system tries to set an impossible duty cycle (e.g., 110%) while V_{OUT} does not rise at all and the next zone is never entered. Additional dead zone margin could be added to deal with this problem, but the load, components, and layout will also need more margin, which generally means a less efficient system.

Accordingly, some embodiments of the present invention utilize a voltage mode control system in which a compensation voltage V_{COMP}, while based in part on V_{OUT}, is linearly related to a fixed sawtooth waveform and where a PWM duty cycle d is linearly related to V_{COMP}. An advantage of this approach is that V_{COMP} can be sensed to determine zones (including dead zones) and manipulated directly to produce suitable PWM duty cycles d in such zones. However, in some applications, it may be useful to use a current mode control system, particularly when using 3-state PWM cycles.

In addition, the inventive voltage mode control system enables reduction in the total margin used for defining dead zones since no added margin is needed to account for parasitics in the power stages of a power converter. Further, the inventive voltage mode control system maintains regulation throughout transitions from a first zone to a dead zone to a second zone, and such transitions can be made essentially seamless without knowledge of the external circuit components (e.g., values for the inductor L or the output capacitor C_{OUT}). Moreover, all pulses—inside and outside dead zones—can be regulated.

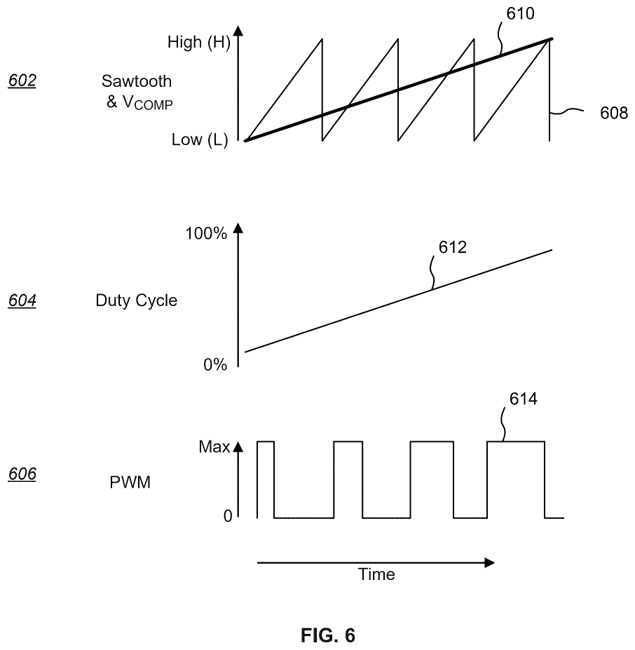

Some embodiments of the present invention beneficially take advantage of one aspect of a voltage mode control system—a fixed sawtooth waveform within a PWM generator circuit that does not depend on load current. For example, FIG. 6 is a set of related subgraphs 602-606 showing various characteristics of a voltage mode PWM generator circuit as a function of time. Subgraph 602 shows a fixed sawtooth waveform 608 that ranges between a low voltage value L and a high voltage value H. Overlaying the fixed sawtooth waveform 608 is a graph line 610 showing possible values for V_{COMP}. Since the fixed sawtooth waveform 608 does not depend on the load current, a duty cycle d can be determined to be d=(V_{COMP}−L)/(H−L), where the values of H and L are known ahead of time and parasitics are ignored. Subgraph 604 shows a graph line 612 representing the linearity of the PWM duty cycle d. Subgraph 606 shows a graph line 614 of PWM cycles with increasing duty cycles d corresponding to the increase of graph line 612 over time in subgraph 604. If the ESR of the external inductor L is high or if the load current is high, V_{COMP} will exceed the maximum duty cycle allowed by a specified dead zone margin, thus indicating a need to transition to higher switching levels. Stated another way, V_{COMP} in a voltage mode control system could correctly indicate a zone-to-zone transition is needed while V_{OUT} alone may not accurately indicate a transition due to a high ESR or high load current.

A voltage mode control system alone does not resolve all design issues. Transitioning between a normal zone and a dead zone should be seamless so the inductor current I_{L} and output voltage V_{OUT} to avoid large spikes. Taking advantage of the fact that the PWM duty cycle d is linearly related to V_{COMP} in a voltage mode control system, when shifting between zones (e.g., Zone 1 with duty cycle dₘₐₓ to Zone 2 with duty cycle dₘᵢₙ), embodiments of the present invention beneficially alternate the duty cycles of pairs of adjacent PWM cycles to achieve a smooth transition using a “duty cycle level shifter” circuit and associated method. Beneficial characteristics of an improved voltage mode control system in accordance with the present invention include: (1) maintaining the voltage V_{Lx} at node Lx and the voltage V_{L} across the inductor L constant during zone transitions to avoid substantial changes (e.g., large spikes) in V_{OUT}; and (2) regulating an M-level converter cell at all times without exceeding dₘₐₓ or dₘᵢₙ limits—that is, all PWM voltage pulses must have a duty cycle d between dₘₐₓ and dₘᵢₙ, including within dead zones (DZ) and at zone transitions.

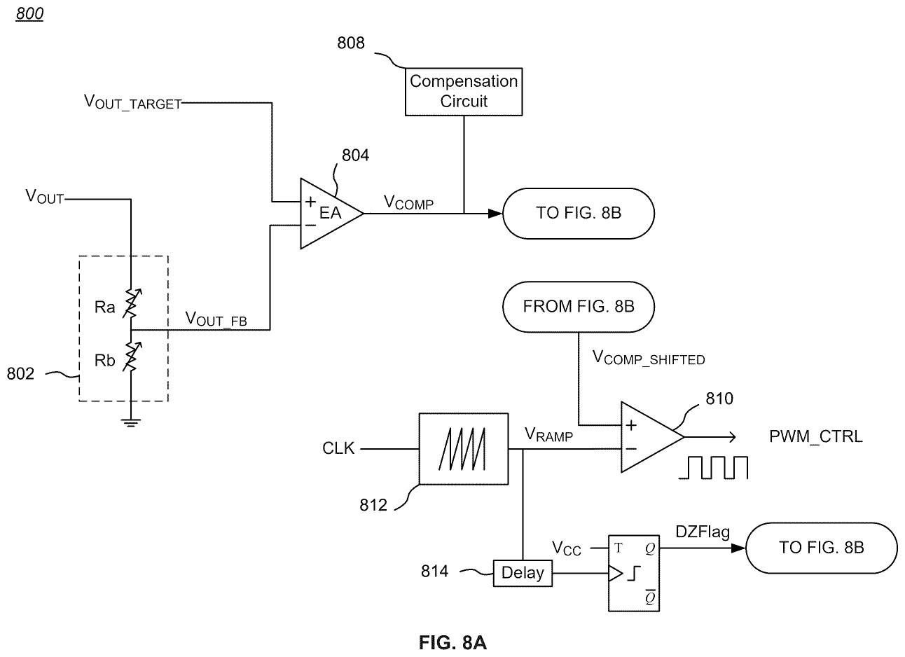

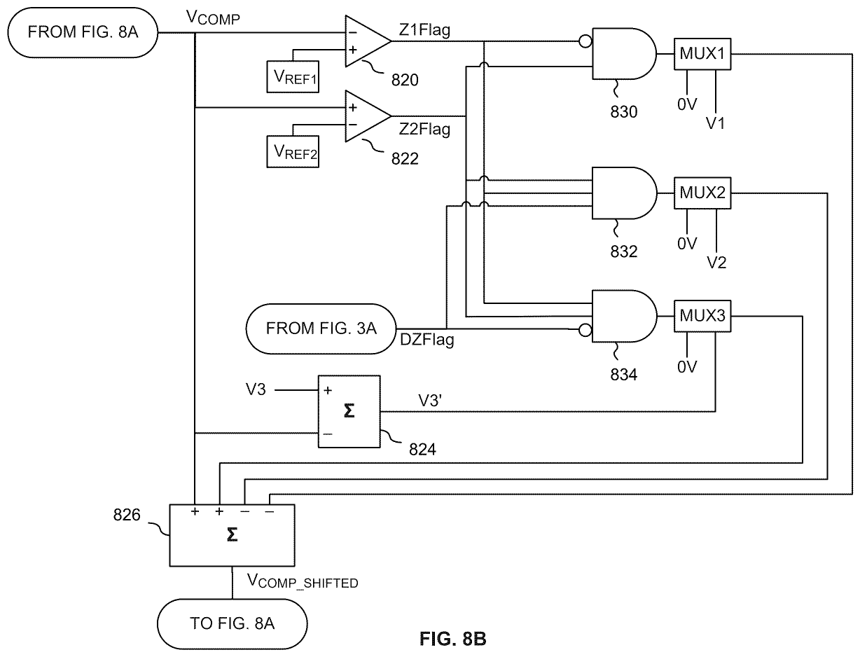

For example, if dₘₐₓ=90% and dₘᵢₙ=10%, then let the duty cycle thresholds for transition between a first zone and DZ be d_{TRAN1}=dₘₐₓ (FirstZone and DZ) and for transition between DZ and a second zone be d_{TRAN2}=1+dₘᵢₙ (DZ and SecondZone). Note that a particular value of V_{COMP} may result in a “requested” duty cycle d above 100%, but the duty cycle level shifter of FIG. 8B will ensure the duty cycle d is always between dₘₐₓ and dₘᵢₙ limits (e.g., 90% and 10%). A “requested” duty cycle d is just the duty cycle that would be needed to produce a desired output if switching in Zone 1 only—obviously, a system cannot actually generate a 110% duty cycle, hence such a value is a “requested” duty cycle. Thus, a “requested” duty cycle d_{REQ'D} of, for example, 110% means the system should be in Zone 2 rather than in Zone 1, with an effective Zone 2 duty cycle of d_{EFF}=d_{REQ'D}−1, which in this example would equal dₘᵢₙ. This also happens to be the transition boundary between DZ and Zone 2, since dₘᵢₙ is the minimum effective duty cycle d_{EFF} needed in any zone.

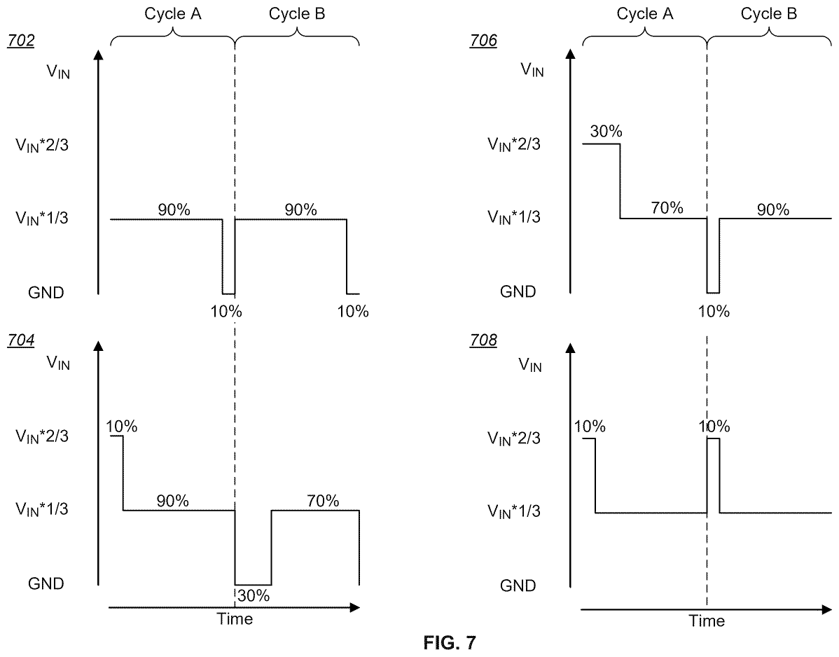

FIG. 7 is a set of related subgraphs 702-708 showing a sequence of dead zone characteristics of an improved voltage mode control system as a function of time. In the illustrated examples, when transitioning from a first zone (e.g., Zone 1 between V_{IN}*⅓ and 0V) to a second zone (e.g., Zone 2 between V_{IN}*⅓ and V_{IN}*⅔), PWM cycles are treated in adjacent pairs, Cycle A and Cycle B. The average switching frequency is constant. Assume that dₘₐₓ=90% and dₘᵢₙ=10%.

Subgraph 702 shows that the duty cycle d in Zone 1 is at 90% of V_{IN}*⅓ for both Cycle A and Cycle B, and thus ready to transition into a dead zone DZ. The resulting average voltage <V_{Lx}> at node Lx is thus 0.9*V_{IN}*⅓.

Subgraph 704 shows separate 2-state duty cycles within the DZ for both Cycle A and Cycle B that together span 3 voltage states. A first 2-state duty cycle for Cycle A includes 10% of V_{IN}*⅔+90% of V_{IN}*⅓. A second 2-state duty cycle for Cycle B includes 30% of 0V +70% of V_{IN}*⅓. The resulting average voltage <V_{Lx}> at node Lx is thus (0.1*V_{IN}*⅔+1.6*V_{IN}*⅓)/2, or 0.9*V_{IN}*⅓—which matches the last average voltage <V_{Lx}> at node Lx in Zone 1. Accordingly, the transition from Zone 1 to the DZ is essentially seamless. From periodic steady state theory, if the average voltage <V_{L}> across the inductor L is nonzero, the inductor current IL will change. Thus, if <V_{Lx}> changes during a zone transition, <V_{L}> changes, and V_{OUT} will have an undesirable spike, whereas if <V_{Lx}> remains steady during a zone transition, <V_{L}> does not change, thus avoiding a large spike at V_{OUT}.

Subgraph 706 shows 3-state duty cycles within the DZ for both Cycle A and Cycle B. A 2-state duty cycle for Cycle A has been ramped up to 30% of V_{IN}*⅔+70% of V_{IN}*⅓. A separate 2-state duty cycle for Cycle B has been ramped down to 10% of 0V+90% of V_{IN}*⅓. The resulting average voltage V_{Lx} at node Lx is thus (0.3*V_{IN}*⅔+0.6*V_{IN}*⅓)/2, or 1.1*V_{IN}*⅓.

Subgraph 708 shows that the duty cycle d in Zone 1 is at 10% of V_{IN}*⅔ for both Cycle A and Cycle B after the transition from the DZ. The resulting average voltage <V_{Lx}> at node Lx is thus 1.1*V_{IN}*⅓—which matches the last average voltage <V_{Lx}> at node Lx in the DZ. Accordingly, the transition from the DZ to Zone 2 is essentially seamless.

Of note, the states represented by subgraph 704 and subgraph 706 are endpoints of a smooth and symmetrical transformation of the separate 2-state duty cycles within Cycle A and Cycle B, respectively. As the upper voltage (e.g., V_{IN}*⅔) percentage increases over time in Cycle A (e.g., in 1% to 10% steps in a partially digital control system, or continuously in an analog control system), the lower voltage (e.g., 0V) percentage decreases over the same time period in corresponding equal steps—that is, the duty cycle levels shift over time. For example, starting with the states shown in subgraph 704 and assuming evaluation at 1% adjustment intervals, the 2-state duty cycle for Cycle A may adjust to 11% of V_{IN}*⅔+89% of V_{IN}*⅓, then to 12% of V_{IN}*⅔+88% of V_{IN}*⅓, etc., ending with 30% of V_{IN}*⅔+70% of V_{IN}*⅓. Correspondingly, the 2-state duty cycle for Cycle B may adjust to 29% of 0V+71% of V_{IN}*⅓, then to 28% of 0V+72% of V_{IN}*⅓, etc., ending with 10% of 0V+90% of V_{IN}*⅓.

Note that Cycle A has a leading 2-state duty cycle, with the highest voltage at the beginning edge of the PWM cycle followed by a lower voltage, while Cycle B has a trailing 2-state duty cycle, with the lowest voltage at the beginning edge of the PWM cycle followed by a higher voltage. Stated in other ways, the 2-state duty cycle in Cycle A is opposite in phase from the 2-state duty cycle in Cycle B, or alternatively, the 2-state duty cycle of Cycle B is the inverse of the 2-state duty cycle of Cycle A. The inverse duty cycle d for a 2-state PWM cycle

is the ratio of time the PWM waveform is at the lowest voltage within a zone relative to the duration of the PWM cycle. In some embodiments, Cycle A may have a trailing 2-state duty cycle while Cycle B may have a leading 2-state inverse duty cycle. In some embodiments, the phasing of the 2-state duty cycles in Cycle A and Cycle B may alternate (e.g., in one pair of PWM cycles, Cycle A may have a leading 2-state duty cycle and Cycle B may have a trailing 2-state inverse duty cycle, while in a different pair of PWM cycles, Cycle A may have a trailing 2-state inverse duty cycle and Cycle B may have a leading 2-state duty cycle).

Note also that while Cycle B has an inverse or opposite phase 2-state duty cycle compared to Cycle A, the percentages of each state do not necessarily match the percentages of each state of Cycle A. For example, in subgraph 704, in Cycle A, the 2-state duty cycle is 10% higher voltage, 90% lower voltage, while in Cycle B, the 2-state inverse duty cycle is 30% lower voltage, 70% higher voltage. What is important is that the 2-state duty cycles generate voltages that match the transitions from Zone 1 to the dead zone and from the dead zone to Zone 2, with the 2-state duty cycles of Cycle A and Cycle B shifting over time in synchronization and by equal amounts.

Importantly, the 2-state duty cycles within the DZ for both Cycle A and Cycle B are selected by means of a novel duty cycle level shifter circuit that ensures that the average voltage <V_{Lx}> at node Lx during a transition into or out of the DZ essentially matches the average voltage <V_{Lx}> of the adjacent zone just before the transition. The result is that the average voltage <V_{Lx}> at node Lx smoothly increases from the last average voltage in Zone 1 to the first average voltage in Zone 2, with no discontinuities at the Zone 1 to the DZ transition or at the DZ to Zone 2 transition. Transitions in the opposite direction (Zone 2 to DZ to Zone 1) exhibit the same essentially seamless characteristics, with the average voltage <V_{Lx}> smoothly decreasing from the last average voltage in Zone 2 to the first average voltage in Zone 2. Transitions within the DZ between Zone 2 and Zone 3 at V_{IN}*⅔ follow the same process.

FIGS. 8A and 8B are block diagrams showing one embodiment of a voltage mode PWM generator circuit 800 that includes a duty cycle level shifter circuit for a 4-level converter cell. In the illustrated example, the output voltage V_{OUT} from the converter cell is applied, either directly or as translated to a lower reference point by a scaling circuit 802, to a first input of an error amplifier 804 as a feedback voltage, V_{OUT_FB}. In the illustrated example, the scaling circuit 802 is a resistive divider comprising two resistors Ra, Rb coupled in series between V_{OUT} and

circuit ground, with the scaled output, V_{OUT_FB}, taken from between resistors Ra and Rb and applied to the error amplifier 804. The resistors Ra, Rb are shown as variable or settable, but may be fixed in value. Scaling of V_{OUT} to V_{OUT_FB} may be accomplished by other known circuits.

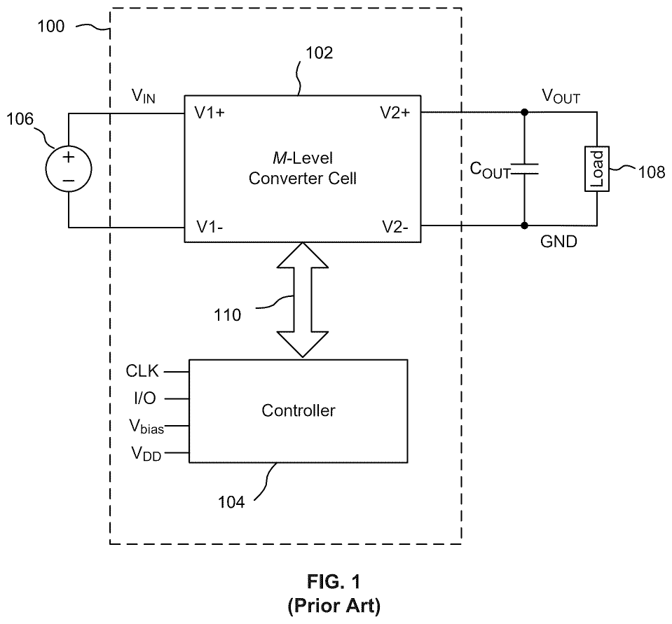

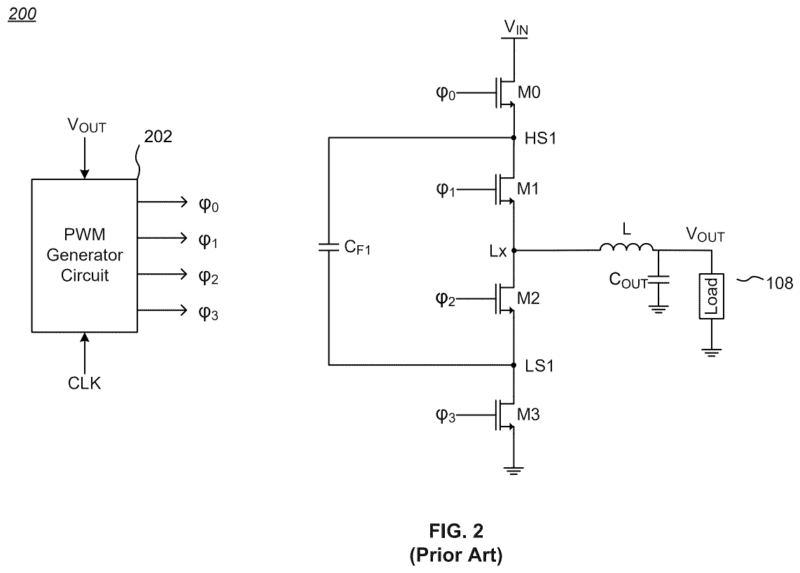

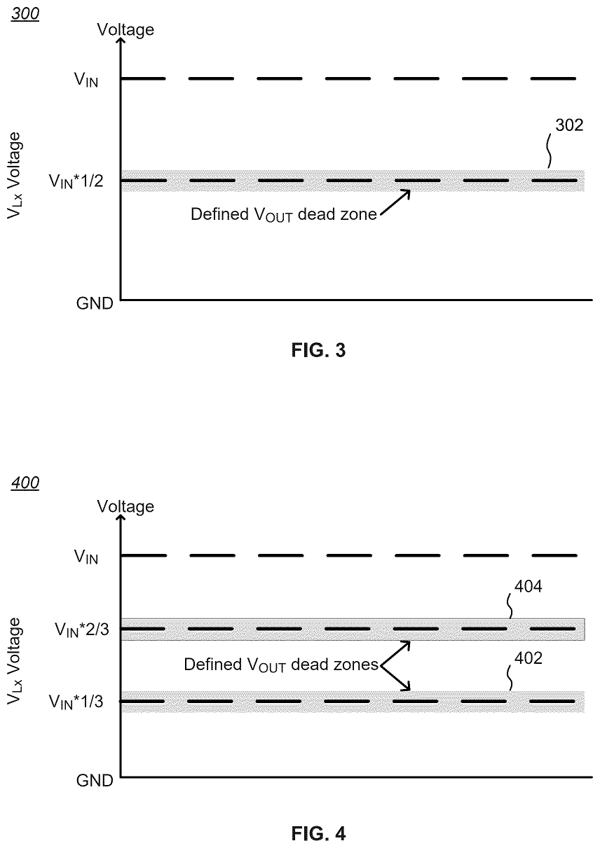

A second input of the error amplifier 804 is a target voltage, V_{OUT_TARGET}, for the output V_{OUT} of a connected DC-to-DC converter circuit 102. V_{OUT_TARGET} changes up or down in value in response to a controlling signal, such as V_{OUT}, in order to change the regulated output voltage V_{OUT} of a connected DC-to-DC converter circuit (for example, the converter cell 102 of FIG. 1). The error amplifier 804 outputs a compensation voltage V_{COMP} based on the inputs V_{OUT_TARGET} and V_{OUT_FB}.

An error amplifier generally has some compensation components, for example, a compensation capacitor, and is not simply a subtractor circuit generating V_{OUT_TARGET}−V_{OUT_FB}. Thus, V_{COMP} is not necessarily exactly equal to the difference of the inputs. It is true that if V_{OUT} goes up, then V_{COMP} will go down, since that is what the positive and negative inputs of an error amplifier will produce. But, since there can be an applied DC voltage (e.g., across a compensation capacitor), there is not a direct connection between V_{COMP} and V_{OUT}. For example, consider the condition where V_{OUT_FB}=V_{OUT_TARGET}. This can happen whenever the converter cell is in steady-state and has precisely reached a desired output voltage. However, this case does not mean that V_{COMP}=0, because that would mean the duty cycle d is zero, which means no power FET is ON. One way to think about it is that in a negative feedback system, V_{COMP} will be whatever value it has to be to make V_{OUT_FB} get equal to V_{OUT_TARGET}. In the case that the ESR of inductor L is very high, for example, a higher value of V_{COMP} than usual is needed to make V_{OUT_FB} get equal to V_{OUT_TARGET}. The value of V_{COMP} will go up as much as needed in order to make this happen and compensate (hence why it is called a “compensation voltage”) for the ESR of inductor L, whatever the ESR may be.

The V_{COMP} output of the error amplifier 804 may be coupled to a compensation circuit 808 configured to stabilize the closed-loop response of the PWM generator circuit 800. The compensation voltage V_{COMP} from FIG. 8A may be modified by the circuitry shown in FIG. 8B to a V_{COMP_SHIFTED} signal.

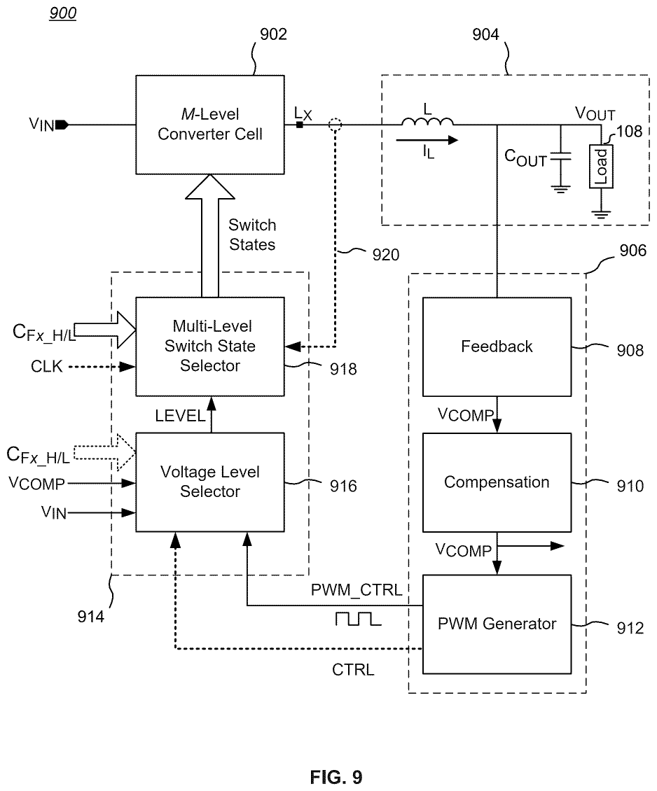

The V_{COMP_SHIFTED} signal from FIG. 8B is coupled to a first input of an analog comparator 810. A second input of the analog comparator 810 is coupled to a voltage ramp generator 812. The voltage ramp generator 812 is generally coupled to a fixed-frequency clock signal CLK and outputs a ramped voltage signal, V_{RAMP}, to the comparator 810. The comparator 810 compares V_{RAMP} to V_{COMP_SHIFTED} and generates a pulse-width modulated control signal PWM_CTRL having a duty cycle that is a function of the comparison. The PWM_CTRL control signal may be applied as shown in FIG. 9, described below.

The V_{RAMP} signal is also applied to a delay circuit 814 having an output coupled to the clock input of a positive-edge toggle-type flip-flop 816. The delay circuit 814 offsets its output from V_{RAMP} to avoid race conditions, and may comprise (as one example) an even-number of inverters coupled in series. The output, DZFlag, of the toggle-type flip-flop 816 is provided to the circuitry in FIG. 8B and is one-half the frequency of the V_{RAMP} signal (i.e., the toggle-type flip-flop 816 provides DZFlag every-other cycle of the V_{RAMP} signal). As should be appreciated, other circuits may be used to create a DZFlag at one-half the frequency of the V_{RAMP} signal.

Referring to FIG. 8B, V_{COMP} is applied to a negative input of a first analog comparator 820, a positive input of a second analog comparator 822, a negative input of a first analog summing circuit 824, and a positive input of a second analog summing circuit 826.

A positive input of the first analog comparator 820 is coupled to a first reference voltage V_{REF1} that defines a transition voltage level (e.g., 1.1V) between a lower zone (Zone 1 in this example) and a DZ. The output of the first analog comparator 820 is a flag, Z1Flag. If V_{COMP}≤V_{REF1}, then Z1Flag is a logic 1, which means V_{COMP} is within the range of Zone 1 or in the DZ.

A negative input of the second analog comparator 822 is coupled to a second reference voltage V_{REF2} that defines a transition voltage level (e.g., 0.9V) between the DZ and an upper zone (Zone 2 in this example). The output of the second analog comparator 822 is a flag, Z2Flag. If V_{COMP}≥V_{REF2}, then Z2Flag is a logic 1, which means V_{COMP} is in the DZ or within the range of Zone 2.

The Z1Flag is coupled to an inverting input of a first AND gate 830 and the Z2Flag is coupled to a non-inverting input of the first AND gate 830. The first AND gate 830 generates a logic 1 output when the Z1Flag is a logic 0 and the Z2Flag is a logic 1, indicating that a Zone 2 adjustment should be made to V_{COMP}. The output of the first AND gate 830 is applied as a selection signal to a first multiplexer MUX1, which outputs either a reference voltage (e.g., 0V) or a first adjustment voltage V1 (e.g., 1.0V). The output of the first multiplexer MUX1 is coupled to a negative input of the second analog summing circuit 826, and thus reduces V_{COMP} when the first adjustment voltage V1 is selected by the first AND gate 830.

The Z1Flag, the Z2Flag, and the DZFlag are coupled to respective non-inverting inputs of a second AND gate 832. The second AND gate 832 generates a logic 1 output when the Z1Flag, the Z2Flag, and the DZFlag are all a logic 1, indicating that a first dead zone adjustment should be made to V_{COMP} when in Cycle B of a pair of dead zone PWM cycles. The output of the second AND gate 832 is applied as a selection signal to a second multiplexer MUX2, which outputs either reference voltage (e.g., 0V) or a second adjustment voltage V2 (e.g., 0.8V). The output of the second multiplexer MUX2 is coupled to a negative input of the second analog summing circuit 826, and thus reduces V_{COMP} when the second adjustment voltage V2 is selected by the first AND gate 832.

The Z1Flag and the Z2Flag are coupled to respective non-inverting inputs of a third AND gate 834, while the DZFlag is coupled to an inverting input of the third AND gate 834. The third AND gate 834 generates a logic 1 output when the Z1Flag and the Z2Flag are both a logic 1 and the DZFlag is a logic 0, indicating that a second dead zone adjustment should be made to V_{COMP} when in Cycle A of a pair of dead zone PWM cycles. The output of the third AND gate 834 is applied as a selection signal to a third multiplexer MUX3, which outputs either reference voltage (e.g., 0V) or a modified third adjustment voltage V3′. The modified third adjustment voltage V3′ is the difference between V_{COMP} and a third adjustment voltage V3 (e.g., 1.2V); more specifically, V_{COMP} is applied to a positive input of the first analog summing circuit 824 and V3 is applied to a negative input of the first analog summing circuit 824, the output of which is the modified third adjustment voltage V3′. The output of the third multiplexer MUX3 is coupled to a positive input of the second analog summing circuit 826, and thus increases V_{COMP} when the third adjustment voltage V3′ is selected by the third AND gate 834.

The values for V_{REF1}, V_{REF2}, V1, V2, and V3 should be selected to maintain the PWM duty cycle within selected values for dₘₐₓ and dₘᵢₙ.

Being within a dead zone is indicated by V_{COMP} having a value that causes both the Z1Flag and the Z2Flag to be a logic 1. The first AND gate 830 will select the reference voltage (e.g., 0V) as the output of MUX1. The DZFlag will alternately cause the second AND gate 832 to select V2 as the output of MUX2 and the third AND gate 834 to select V3′ as the output of MUX3. When transitioning from a lower zone (e.g., Zone 1) to a higher zone (e.g., Zone 2), and while in the intervening dead zone, V_{COMP} will ramp up, causing V_{COMP_SHIFTED} to ramp up but with different adjustments for Cycle A and Cycle B. When the DZFlag is a logic 1, MUX2 will subtract V2 from V_{COMP} to reduce the 2-state inverse duty cycle in Cycle B. When the DZFlag is a logic 0, MUX2 will add V3′ to V_{COMP} to increase the 2-state duty cycle in Cycle A (keeping in mind that V3′, equal to the difference between V3 and V_{COMP}, decreases as V_{COMP} increases).

In operation, the output V_{COMP_SHIFTED} of the second analog summing circuit 826—which effectively determines the PWM duty cycle—is a value between 0 and 1 (representing 0% and 100%) and may be (1) V_{COMP} without any shift or adjustment when in Zone 1, (2) V_{COMP} shifted downward when transitioning from Zone 1 into Zone 2 and shifted upward when transitioning from Zone 2 into Zone 1, (3) V_{COMP} shifted downward (for a shorter 2-state inverse duty cycle) when in the dead zone DZ and in Cycle B, or (4) V_{COMP} shifted upward (for a longer 2-state duty cycle) when in the dead zone DZ and in Cycle A.

Note that the circuitry shown in FIG. 8B also applies to transitions from Zone 2 through the DZ to Zone 1. Note also that while circuitry shown in FIG. 8B provides V_{COMP_SHIFTED} for adjacent Zone 1 and Zone 2 of the example 4-level converter cell, similar circuitry with different values for V_{REF1}, V_{REF2}, V1, V2, and V3 may be used to provide V_{COMP_SHIFTED} for adjacent Zone 2 (between V_{IN}*⅓ and V_{IN}*2/3) and Zone 3 (between V_{IN}*⅔ and V_{IN}).

As should be appreciated, other circuits may be devised that implement the patterns of dead zone duty cycle adjustments shown in FIG. 7 so as to achieve smooth transitions when moving from a zone into a dead zone and when moving from a dead zone to a zone.

FIG. 9 is a block diagram of one embodiment of control circuitry 900 for an M-level converter cell 902 coupled to an output block 904 comprising an inductor L and an output capacitor C_{OUT}. Note that, conceptually, the inductor L also may be considered as being included within the M-level converter cell 902. This example control circuitry 900 is adapted from the teachings set forth in U.S. patent application Ser. No. 17/560,767, filed Dec. 23, 2021, entitled “Controlling Charge-Balance and Transients in a Multi-Level Power Converter”, assigned to the assignee of the present invention, the contents of which are incorporated by reference. However, the present invention may be used in combination with other types of control circuitry for an M-level converter cell 902.

The control circuitry 900 functions as a control loop coupled to the output of the M-level converter cell 902 and to power-switch control inputs of the M-level converter cell 902. In general, the control circuitry 900 is configured to monitor the output (e.g., voltage and/or current) of the M-level converter cell 902 and dynamically generate a set of power-switch control inputs to the M-level converter cell 902 that attempt to stabilize the output voltage V_{OUT} and/or output current at specified values, taking into account variations of V_{IN} and output load. The control circuitry 900 may be incorporated into, or separate from, the overall controller 104 for a power converter 100 embodying the M-level converter cell 902, and portions of the control circuitry 900 may be implemented with a digital micro-controller.

A first block comprises a feedback controller 906, which is preferably a voltage mode control system in accordance with the present invention. The feedback controller 906 is shown as being coupled to V_{OUT}. In alternative embodiments, the feedback controller 906 may be configured to monitor the input of the M-level converter cell 902 and/or an internal node of the M-level converter cell 902. The feedback controller 906 produces a signal directly or indirectly indicative of the voltage at V_{OUT} that determines in general terms what needs to be done in the M-level converter cell 902 to maintain desired values for V_{OUT}: charge, discharge, or tri-state (i.e., open, with no current flow).

In the illustrated example, the feedback controller 906 includes a feedback circuit 908, a compensation circuit 910, and a pulse-width modulation (PWM) generator 912. The feedback circuit 908 may include, for example, a feedback-loop voltage detector which compares V_{OUT} (or an attenuated version of V_{OUT}) to a reference voltage which represents a desired V_{OUT} target voltage (which may be dynamic) and outputs a control signal to indicate whether V_{OUT} is above or below the target voltage. The feedback-loop voltage detector may be implemented with a comparison device, such as an operational amplifier (op-amp) or transconductance amplifier (gm amplifier). An output of the feedback circuit 908 is V_{COMP}.

The compensation circuit 910 is configured to stabilize the closed-loop response of the feedback controller 906 by avoiding the unintentional creation of positive feedback, which may cause oscillation, and by controlling overshoot and ringing in the step response of the feedback controller 906. The compensation circuit 910 may be implemented in known manner and may include LC and/or RC circuits. An output of the compensation circuit 910 is V_{COMP} as modified by the compensation circuit 910.

The PWM generator 912 generates the actual PWM control signal PWM_CTRL which ultimately sets the duty cycle of the power switches of the M-level converter cell 902. In some embodiments, the PWM generator 912 may pass on additional optional control signals CTRL indicating, for example, the magnitude of the difference between V_{OUT} and a reference voltage (thus indicating that some levels of the M-level converter cell 902 should be bypassed to get to higher or lower levels), and the direction of that difference (e.g., V_{OUT} being greater than or less than the reference voltage). In other embodiments, the optional control signals CTRL can be derived from the output of the compensation circuit 910, or from the output of the feedback circuit 908, or from a separate comparator (not shown) coupled to, for example, V_{OUT}. One purpose of the optional control signals CTRL is for advanced control algorithms, when it may be beneficial to know how far away V_{OUT} is from a target output voltage, thus allowing faster charging of the inductor L if V_{OUT} is severely under-regulated. As should be appreciated, the PWM generator 912 may be an embodiment of the voltage mode PWM generator circuit 800 described above.

A second block comprises an M-level controller 914, the primary function of which is to select the power switch states that generate a desired value for V_{OUT} while maintaining a charge-balance state on the fly capacitors within the M-level converter cell 902 every time an output voltage level is selected, regardless of what power switch state or states were used in the past.

The M-level controller 914 includes a Voltage Level Selector 916 which receives the PWM_CTRL control signal and the additional control signals CTRL if available. In addition, the Voltage Level Selector 916 may be coupled to V_{COMP} and/or V_{IN}, and, in some embodiments, to HIGH/LOW voltage status signals, C_{Fx_H/L}, from voltage detectors (not shown) coupled across corresponding fly capacitors C_{Fx} within the M-level converter cell 902. A function of the Voltage Level Selector 916 is to translate the received signals to a target output voltage level (e.g., on a cycle-by-cycle basis). The Voltage Level Selector 916 typically will consider at least V_{COMP} and/or V_{IN} to determine which target level should charge or discharge the output of the M-level converter cell 902 with a desired rate, and may take into account the voltage across each fly capacitor.

The output of the Voltage Level Selector 916 is coupled to an M-level Switch State Selector 918, which generally would be coupled to the voltage status signals, C_{Fx_H/L}, from the capacitor voltage detectors for the fly capacitors C_{Fx}. Taking into account the target level generated by the Voltage Level Selector 916, the M-level Switch State Selector 918 determines which power switch states for the desired output level should be preferred for capacitor charge-balance. The output of the M-level Switch State Selector 918 is coupled to the power FETs of the M-level converter cell 902 (through appropriate level-shifter circuits and drivers circuits, as may be needed for a particular converter cell) and includes the power switch state settings determined by the M-level Switch State Selector 918 (which selects the configuration of power FETs within the M-level converter cell 902 corresponding to a selected target level).

In general (but not always), the Voltage Level Selector 916 and the M-level Switch State Selector 918 only change their states when the PWM_CTRL signal changes. For example, when the PWM_CTRL signal goes high, the Voltage Level Selector 916 may select which level results in charging of the inductor L and the M-level Switch State Selector 918 may set which version of switch settings to use for that level. Then when the PWM_CTRL signal goes low, the Voltage Level Selector 916 may select which level should discharge the inductor L and the M-level Switch State Selector 918 may set which version of that level to use. Thus, the Voltage Level Selector 916 and the M-level Switch State Selector 918 generally only change states when the PWM_CTRL signal changes (the PWM_CTRL signal is in effect their clock signal). However, there may be situations or events where it is desirable for the CTRL signals to change the state of the Voltage Level Selector 916. In some embodiments, it may be useful to include a timing function that forces the M-level Switch State Selector 918 to re-evaluate the optimal version of the power switch state periodically, for example, in order to avoid being “stuck” at one level for a very long time, potentially causing charge imbalances.

In embodiments that utilize the teachings set forth in the patent application entitled “Controlling Charge-Balance and Transients in a Multi-Level Power Converter” referenced above, the M-level controller 914 implements a control method for the M-level converter cell 902 that selects an essentially optimal power switch state which moves the fly capacitors C_{Fx} towards a charge-balance state every time a voltage level at the Lx node is selected, regardless of what power switch state or states were used in the past. Accordingly, such M-level converter circuits are free to select a different power switch state or Lx voltage level every switching cycle without a need to keep track of any prior power switch state or sequence of power switch states.

In some embodiments, the M-level Switch State Selector 918 may take into account the magnitude and/or polarity of current IL flowing through the inductor L by way of an optional current-measurement input 920, which may be implemented in conventional fashion.

One notable benefit of the control circuitry shown in FIG. 9 is that it enables generation of voltages in boundary zones between voltage levels, which represent unattainable output voltages for conventional M-level DC-to-DC converter circuits.

While FIG. 9 shows a particular embodiment of control circuitry for an M-level converter cell as modified in accordance with the present invention, it should be appreciated that other control circuits may be adapted or devised to provide suitable switching signals for the power switches within a converter cell while still being able to use embodiments of the present invention.

It may be desirable to provide additional control and operational circuitry (or one or more shutdown procedures) that enables reliable and efficient operation of a power converter utilizing an M-level converter cell designed in accordance with the present disclosure. For example, in a step-down power converter, the output voltage of a converter cell is less than the input voltage of the converter cell. Shutting down or disabling (e.g., because of a fault event, such as a short) a converter cell having a designed-in inductance connected to the output while the output load current is non-zero generally requires some means for discharging the inductor current. In some embodiments, a bypass switch may be connected in parallel with a designed-in inductance connected to the output of a converter cell and controlled to be open during normal operation and closed when shutting down the converter cell or if a fault event occurs. Ideally, in order to prevent transient ringing and to provide safe discharge of the inductor current, the bypass switch can be closed before disabling converter cell switching. In alternative embodiments using MOSFETs for the main power switches of the converter, the inherent body diode connected between the body and drain terminals of each MOSFET can also discharge the inductor current. Details of these solutions, as well as alternative shutdown solutions, are taught in U.S. Pat. No. 10,686,367, issued Jun. 16, 2020, entitled “Apparatus and Method for Efficient Shutdown of Adiabatic Charge Pumps”, assigned to the assignee of the present invention, the contents of which are incorporated by reference.

Another consideration when combining converter cells in parallel is controlling multiple parallel power converters in order to avoid in-rush current (e.g., during a soft-start period for the power converters) and/or power switch over-stress if all of the power converters are not fully operational, such as during startup or when a fault condition occurs. Conditional control may be accomplished by using node status detectors coupled to selected nodes within parallel-connected power converters to monitor voltage and/or current. Such node status detectors may be configured in some embodiments to work in parallel with an output status detector measuring the output voltage of an associated power converter during startup. The node status detectors ensure that voltages across important components (e.g., fly capacitors and/or power switches) within the converter cell(s) of the power converters are within desired ranges before enabling full power steady-state operation of the parallel power converters, and otherwise prevent full power steady-state operation. The node status detectors may be coupled to a master controller that controls one or more of the parallel power converters using one or more common control signals. In furtherance of a master controller configuration, the parallel power converters may each report a power good signal (Pgood) when ready to leave a startup phase for full power steady-state operation. The master controller may essentially “AND” all such Pgood signals together, possibly along with one or more status signals from other circuits, such that the master controller does not enable full power steady-state operation of any the parallel power converter unless all of the parallel power converters are ready for that state. In essence, the Pgood signals from each parallel power converter are all tied together such that the parallel power converters may not transition out of startup phase until all the Pgood signals indicate that they are ready to transition to steady operation. Furthermore, if the Pgood signal changes due to a fault condition in one or more of the parallel power converters, the parallel power converters can transition from a steady state operation to an auto-restart or shutdown operation. Details of these solutions, as well as alternative shutdown solutions, are taught in U.S. Pat. No. 10,992,226, issued Apr. 27, 2021, entitled “Startup Detection for Parallel Power Converters”, assigned to the assignee of the present invention, the contents of which are incorporated by reference.

Another solution to balancing capacitor voltages in an M-level DC-to-DC converter circuit is to provide a lossless voltage balancing solution where out-of-order state transitions of the converter cell are allowed to take place during normal operation. The net effect of out-of-order state transitions is to increase or decrease the voltage across specific fly capacitors, thus preventing voltage overstress on the main power switches of the DC-to-DC converter. In some embodiments, restrictions are placed on the overall sequence of state transitions to reduce or avoid transition state toggling, thereby allowing each capacitor an opportunity to have its voltage steered as necessary, rather than allowing one capacitor to be voltage balanced before voltage balancing another capacitor. Details of this solution, as well as alternative charge balancing solutions, are taught in U.S. Pat. No. 10,770,974, issued Sep. 8, 2020, entitled “Multi-Level DC-DC Converter with Lossless Voltage Balancing”, assigned to the assignee of the present invention, the contents of which are incorporated by reference.

An additional consideration for some embodiments is enabling operation of M-level converter cells such that voltages can be generated in boundaries zones between voltage levels. “Boundary zones” represent unattainable output voltages for conventional M-level DC-to-DC converter circuits. In order to generate output voltages within a boundary zone, some embodiments essentially alternate (toggle) among adjacent (or even nearby) zones by setting states of the converter cell power switches in a boundary zone transition pattern. For example, a 3-level DC-to-DC converter circuit may operate in Zone 1 for a selected time and in adjacent Zone 2 for a selected time. Thus, Zones 1 and 2 are treated as a single “super-zone”. More generally, in some cases, it may be useful to create super-zones using non-adjacent zones or using more than two zones (adjacent and/or non-adjacent). Details of this solution are taught in U.S. Pat. No. 10,720,842, issued Jul. 21, 2020, entitled “Multi-Level DC-DC Converter with Boundary Transition Control”, assigned to the assignee of the present invention, the contents of which are incorporated by reference.

Yet another consideration for some embodiments is protection of the main power switches and other components within a power converter from stress conditions, particular from voltages that exceed the breakdown voltage of such power switches (particularly FET switches). One means for protecting an M-level power converter uses at least one high-voltage FET power switch while allowing all or most other main power switches to be low-voltage FET switches.

More generally, M-level power converters provide or enable numerous benefits and advantages, including:
adaptability to applications in which input and/or output voltages may have a wide dynamic-range (e.g., varying battery input voltage levels, varying output voltages);
efficiency improvements on the run-time of devices operating on portable electrical energy sources (batteries, generators or fuel cells using liquid or gaseous fuels, solar cells, etc.);
efficiency improvements where efficiency is important for thermal management, particularly to protect other components (e.g., displays, nearby ICs) from excessive heat;
enabling design optimizations for power efficiency, power density, and form-factor of the power converter—for example, smaller-size M-level power converters may allow placing power converters in close proximity to loads, thus increasing efficiency, and/or to lower an overall bill of materials;
the ability to take advantage of the performance of smaller, low voltage transistors;
adaptability to applications in which power sources can vary widely, such as batteries, other power converters, generators or fuel cells using liquid or gaseous fuels, solar cells, line voltage (AC), and DC voltage sources (e.g., USB, USB-C, power-over Ethernet, etc.);
adaptability to applications in which loads may vary widely, such as ICs in general (including microprocessors and memory ICs), electrical motors and actuators, transducers, sensors, and displays (e.g., LCDs and LEDs of all types);
the ability to be implemented in a number of IC technologies (e.g., MOSFETs, GaN, GaAs, and bulk silicon) and packaging technologies (e.g., flip chips, ball-grid arrays, wafer level scale chip packages, wide-fan out packaging, and embedded packaging).

As should be clear, the M-level power converter embodiments described in this disclosure may be synergistically combined with the teachings of one or more of the additional control and operational circuits and methods described in this section.

Further, embodiments of the current invention improve the power density and/or power efficiency of incorporating circuits and circuit modules or blocks. As a person of ordinary skill in the art should understand, a system architecture is beneficially impacted utilizing embodiments of the current invention in critical ways, including lower power and/or longer battery life. The current invention therefore specifically encompasses system-level embodiments that are creatively enabled by inclusion in a large system design and application.

Circuits and devices in accordance with the present invention may be used alone or in combination with other components, circuits, and devices. Embodiments of the present invention may be fabricated as integrated circuits (ICs), which may be encased in IC packages and/or in modules for ease of handling, manufacture, and/or improved performance. In particular, IC embodiments of this invention are often used in modules in which one or more of such ICs are combined with other circuit components or blocks (e.g., filters, amplifiers, passive components, and possibly additional ICs) into one package. The ICs and/or modules are then typically combined with other components, often on a printed circuit board, to form part of an end-product such as a cellular telephone, laptop computer, or electronic tablet, or to form a higher-level module which may be used in a wide variety of products, such as vehicles, test equipment, medical devices, etc. Through various configurations of modules and assemblies, such ICs typically enable a mode of communication, often wireless communication.

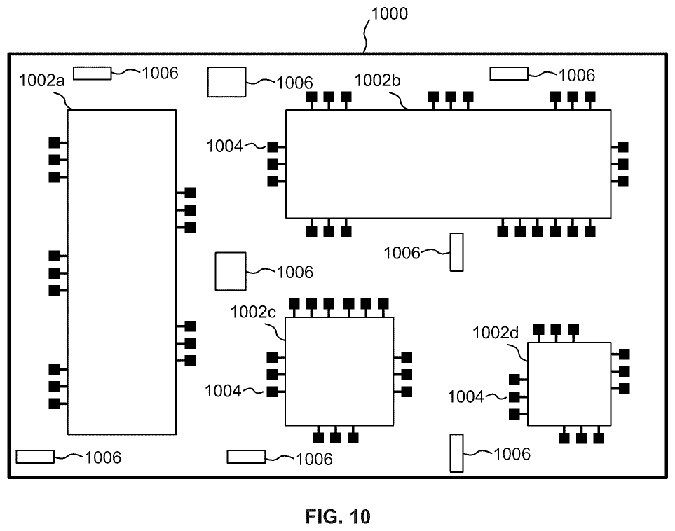

As one example of further integration of embodiments of the present invention with other components, FIG. 10 is a top plan view of a substrate 1000 that may be, for example, a printed circuit board or chip module substrate (e.g., a thin-film tile). In the illustrated example, the substrate 1000 includes multiple ICs 1002a-1002d having terminal pads 1004 which would be interconnected by conductive vias and/or traces on and/or within the substrate 1000 or on the opposite (back) surface of the substrate 1000 (to avoid clutter, the surface conductive traces are not shown and not all terminal pads are labelled). The ICs 1002a-1002d may embody, for example, signal switches, active and/or passive filters, amplifiers (including one or more LNAs), and other circuitry. For example, IC 1002b may incorporate one or more instances of a power converter circuit like the circuits described in this disclosure.

The substrate 1000 may also include one or more passive devices 1006 embedded in, formed on, and/or affixed to the substrate 1000. While shown as generic rectangles, the passive devices 1006 may be, for example, filters, capacitors, inductors, transmission lines, resistors, antennae elements, transducers (including, for example, MEMS-based transducers, such as accelerometers, gyroscopes, microphones, pressure sensors, etc.), batteries, etc., interconnected by conductive traces on or in the substrate 1000 to other passive devices 1006 and/or the individual ICs 1002a-1002d. The front or back surface of the substrate 1000 may be used as a location for the formation of other structures.

Embodiments of the present invention are useful in a wide variety of larger radio frequency (RF) circuits and systems for performing a range of functions, including (but not limited to) impedance matching circuits, RF power amplifiers, RF low-noise amplifiers (LNAs), phase shifters, attenuators, antenna beam-steering systems, charge pump devices, RF switches, etc. Such functions are useful in a variety of applications, such as radar systems (including phased array and automotive radar systems), radio systems (including cellular radio systems), and test equipment.

Radio system usage includes wireless RF systems (including base stations, relay stations, and hand-held transceivers) that use various technologies and protocols, including various types of orthogonal frequency-division multiplexing (“OFDM”), quadrature amplitude modulation (“QAM”), Code-Division Multiple Access (“CDMA”), Time-Division Multiple Access (“TDMA”), Wide Band Code Division Multiple Access (“W-CDMA”), Global System for Mobile Communications (“GSM”), Long Term Evolution (“LTE”), 5G, 6G, and WiFi (e.g., 802.11a, b, g, ac, ax, be) protocols, as well as other radio communication standards and protocols.

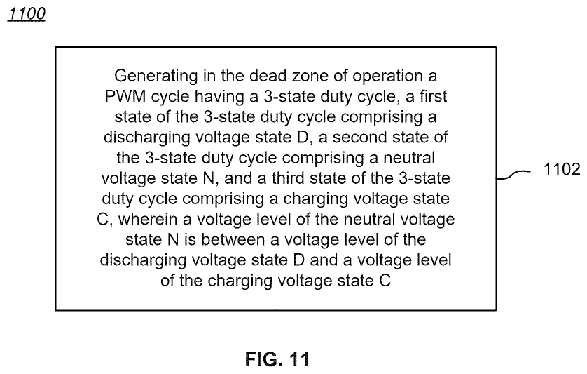

Another aspect of the invention includes methods for implementing the concepts describe above. For example, FIG. 11 is a process flow chart 1100 showing a method of transitioning from a first zone of operation of a PWM generator to a second zone of operation of the PWM generator through a dead zone of operation. The method includes generating in the dead zone of operation a PWM cycle having a 3-state duty cycle, a first state of the 3-state duty cycle comprising a discharging voltage state D, a second state of the 3-state duty cycle comprising a neutral voltage state N, and a third state of the 3-state duty cycle comprising a charging voltage state C, wherein a voltage level of the neutral voltage state N is between a voltage level of the discharging voltage state D and a voltage level of the charging voltage state C (Block 1102).

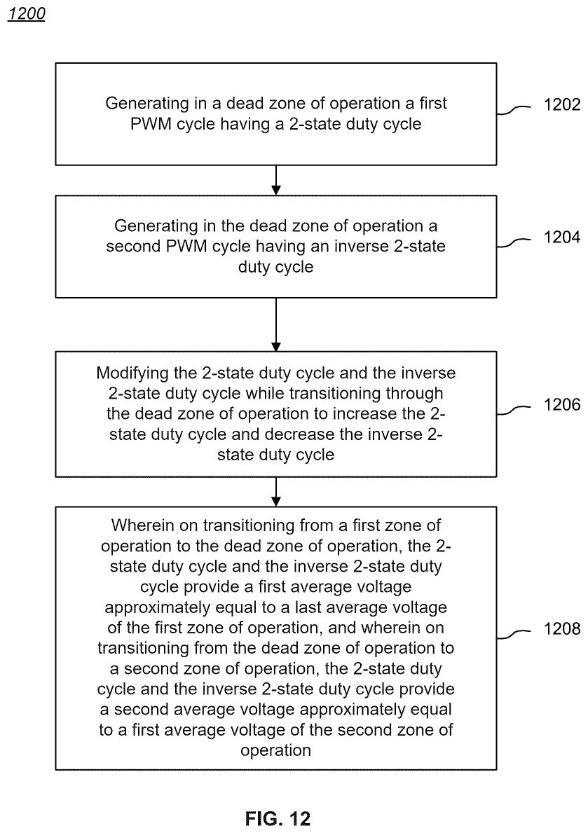

As another example, FIG. 12 is a process flow chart 1200 showing a method of smoothly transitioning from a first zone of operation of a PWM generator to a second zone of operation of the PWM generator through a dead zone of operation. The method includes: generating in a dead zone of operation a first PWM cycle having a 2-state duty cycle (Block 1202); generating in the dead zone of operation a second PWM cycle having an inverse 2-state duty cycle (Block 1204); and modifying the 2-state duty cycle and the inverse 2-state duty cycle while transitioning through the dead zone of operation to increase the 2-state duty cycle and decrease the inverse 2-state duty cycle (Block 1206); wherein on transitioning from a first zone of operation to the dead zone of operation, the 2-state duty cycle and the inverse 2-state duty cycle provide a first average voltage approximately equal to a last average voltage of the first zone of operation, and wherein on transitioning from the dead zone of operation to a second zone of operation, the 2-state duty cycle and the inverse 2-state duty cycle provide a second average voltage approximately equal to a first average voltage of the second zone of operation (Block 1208).

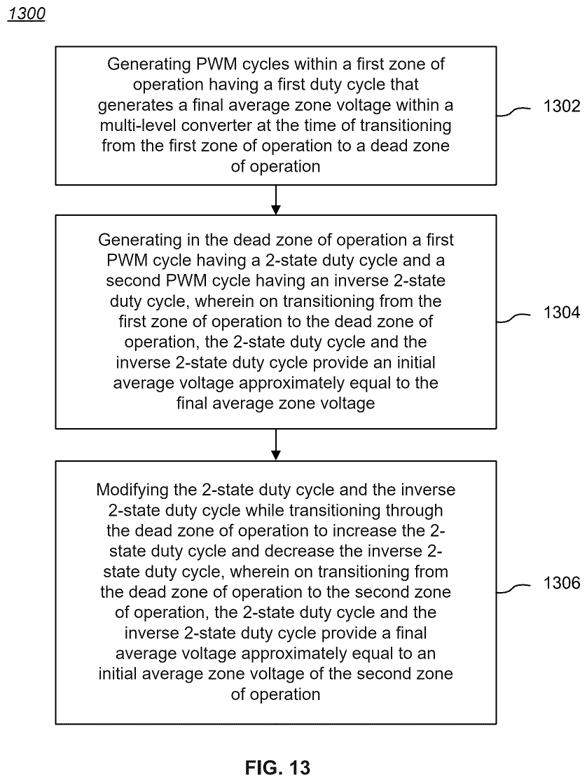

As yet another example, FIG. 13 is a process flow chart 1300 showing a method of smoothly transitioning from a first zone of operation of a PWM generator for a multi-level converter to a second zone of operation of the PWM generator through a dead zone of operation. The method includes: generating PWM cycles within a first zone of operation having a first duty cycle that generates a final average zone voltage within a multi-level converter at the time of transitioning from the first zone of operation to a dead zone of operation (Block 1302); generating in the dead zone of operation a first PWM cycle having a 2-state duty cycle and a second PWM cycle having an inverse 2-state duty cycle, wherein on transitioning from the first zone of operation to the dead zone of operation, the 2-state duty cycle and the inverse 2-state duty cycle provide an initial average voltage approximately equal to the final average zone voltage (Block 1304); and modifying the 2-state duty cycle and the inverse 2-state duty cycle while transitioning through the dead zone of operation to increase the 2-state duty cycle and decrease the inverse 2-state duty cycle, wherein on transitioning from the dead zone of operation to the second zone of operation, the 2-state duty cycle and the inverse 2-state duty cycle provide a final average voltage approximately equal to an initial average zone voltage of the second zone of operation (Block 1306).

The term “MOSFET”, as used in this disclosure, includes any field effect transistor (FET) having an insulated gate whose voltage determines the conductivity of the transistor, and encompasses insulated gates having a metal or metal-like, insulator, and/or semiconductor structure. The terms “metal” or “metal-like” include at least one electrically conductive material (such as aluminum, copper, or other metal, or highly doped polysilicon, graphene, or other electrical conductor), “insulator” includes at least one insulating material (such as silicon oxide or other dielectric material), and “semiconductor” includes at least one semiconductor material.

As used in this disclosure, the term “radio frequency” (RF) refers to a rate of oscillation in the range of about 3 kHz to about 300 GHz. This term also includes the frequencies used in wireless communication systems. An RF frequency may be the frequency of an electromagnetic wave or of an alternating voltage or current in a circuit.

With respect to the figures referenced in this disclosure, the dimensions for the various elements are not to scale; some dimensions may be greatly exaggerated vertically and/or horizontally for clarity or emphasis. In addition, references to orientations and directions (e.g., “top”, “bottom”, “above”, “below”, “lateral”, “vertical”, “horizontal”, etc.) are relative to the example drawings, and not necessarily absolute orientations or directions.

Various embodiments of the invention can be implemented to meet a wide variety of specifications. Unless otherwise noted above, selection of suitable component values is a matter of design choice. Various embodiments of the invention may be implemented in any suitable integrated circuit (IC) technology (including but not limited to MOSFET structures), or in hybrid or discrete circuit forms. Integrated circuit embodiments may be fabricated using any suitable substrates and processes, including but not limited to standard bulk silicon, high-resistivity bulk CMOS, silicon-on-insulator (SOI), and silicon-on-sapphire (SOS). Unless otherwise noted above, embodiments of the invention may be implemented in other transistor technologies, such as bipolar junction transistors (BJTs), BiCMOS, LDMOS, BCD, GaAs HBT, GaN HEMT, GaAs pHEMT, MESFET, InP HBT, InP HEMT, FinFET, GAAFET, and SiC-based device technologies, using 2-D, 2.5-D, and 3-D structures. However, embodiments of the invention are particularly useful when fabricated using an SOI or SOS based process, or when fabricated with processes having similar characteristics. Fabrication in CMOS using SOI or SOS processes enables circuits with low power consumption, the ability to withstand high power signals during operation due to FET stacking, good linearity, and high frequency operation (i.e., radio frequencies up to and exceeding 300 GHz). Monolithic IC implementation is particularly useful since parasitic capacitances generally can be kept low (or at a minimum, kept uniform across all units, permitting them to be compensated) by careful design.

Voltage levels may be adjusted, and/or voltage and/or logic signal polarities reversed, depending on a particular specification and/or implementing technology (e.g., NMOS, PMOS, or CMOS, and enhancement mode or depletion mode transistor devices). Component voltage, current, and power handling capabilities may be adapted as needed, for example, by adjusting device sizes, serially “stacking” components (particularly FETs) to withstand greater voltages, and/or using multiple components in parallel to handle greater currents. Additional circuit components may be added to enhance the capabilities of the disclosed circuits and/or to provide additional functionality without significantly altering the functionality of the disclosed circuits.

A number of embodiments of the invention have been described. It is to be understood that various modifications may be made without departing from the spirit and scope of the invention. For example, some of the steps described above may be order independent, and thus can be performed in an order different from that described. Further, some of the steps described above may be optional. Various activities described with respect to the methods identified above can be executed in repetitive, serial, and/or parallel fashion.

It is to be understood that the foregoing description is intended to illustrate and not to limit the scope of the invention, which is defined by the scope of the following claims, and that other embodiments are within the scope of the claims. In particular, the scope of the invention includes any and all feasible combinations of one or more of the processes, machines, manufactures, or compositions of matter set forth in the claims below. (Note that the parenthetical labels for claim elements are for ease of referring to such elements, and do not in themselves indicate a particular required ordering or enumeration of elements; further, such labels may be reused in dependent claims as references to additional elements without being regarded as starting a conflicting labeling sequence).

What is claimed is:

1. A pulse-width modulated (PWM) generator for a multi-level converter cell, configured to transition from a first zone of operation to a second zone of operation through a dead zone of operation, and to generate in the dead zone of operation a PWM cycle having a 3-state duty cycle, a first state of the 3-state duty cycle comprising a discharging voltage state D, a second state of the 3-state duty cycle comprising a neutral voltage state N, and a third state of the 3-state duty cycle comprising a charging voltage state C, wherein a voltage level of the neutral voltage state N is between a voltage level of the discharging voltage state D and a voltage level of the charging voltage state C.

2. The PWM generator of claim 1, wherein the 3-state duty cycle of the PWM cycle may be implemented as a one of the sequences DCN, DNC, CDN, CND, NCD, or NDC.

3. The PWM generator of claim 1, wherein the PWM generator responds to an external signal to begin and end the 3-state duty cycle.

4. The PWM generator of claim 1, wherein the PWM generator uses an open-loop feed-forward method to begin and end the 3-state duty cycle.

5. The PWM generator of claim 1, wherein the PWM generator uses a closed-loop method to begin and end the 3-state duty cycle.

6. The PWM generator of claim 1, wherein the PWM generator begins or ends the 3-state duty cycle based on a selected parameter being inside or outside a pre-defined range.

7. The PWM generator of claim 1, wherein the PWM generator sets a duration of one of the charging voltage state C or discharging voltage state D by use of an open-loop feed-forward method.

8. The PWM generator of claim 1, wherein the PWM generator sets a duration of one of the charging voltage state C or discharging voltage state D by use of a closed-loop method.

9. The PWM generator of claim 1, wherein the PWM generator sets a duration of one of the charging voltage state C or discharging voltage state D based on a selected parameter being inside or outside a pre-defined range.

10. The PWM generator of claim 1, wherein the PWM generator sets a duration D₁ of the charging voltage state C and a duration D₂ of the discharging voltage state D such that the sum of D₁+D₂ equals a selected constant.

11. A method of transitioning from a first zone of operation of a pulse-width modulated (PWM) generator to a second zone of operation of the PWM generator through a dead zone of operation, including generating in the dead zone of operation a PWM cycle having a 3-state duty cycle, a first state of the 3-state duty cycle comprising a discharging voltage state D, a second state of the 3-state duty cycle comprising a neutral voltage state N, and a third state of the 3-state duty cycle comprising a charging voltage state C, wherein a voltage level of the neutral voltage state N is between a voltage level of the discharging voltage state D and a voltage level of the charging voltage state C.

12. The method of claim 11, wherein the 3-state duty cycle of the PWM cycle may be implemented as a one of the sequences DCN, DNC, CDN, CND, NCD, or NDC.

13. The method of claim 11, wherein to begin and end the 3-state duty cycle, the PWM generator:
responds to an external signal; or
uses an open-loop feed-forward method; or
uses a closed-loop method; or
based on a selected parameter being inside or outside a pre-defined range.

14. The method of claim 11, further including setting a duration of one of the charging voltage
state C or discharging voltage state D using:
an open-loop feed-forward method; or
a closed loop method; or
a selected parameter being inside or outside a pre-defined range; or
further including setting a duration D₁ of the charging voltage state C and a duration D₂ of the discharging voltage state D such that the sum of D₁+D₂ equals a selected constant.

15. A voltage mode control system for a multi-level converter cell, including:
an error amplifier having a first input coupled to a source of a target voltage signal, a second input coupled to a signal representing an output voltage of the multi-level converter cell, and a compensation signal output;
a voltage ramp generator configured to output a ramped voltage signal having a selected frequency;
a comparator having a first input coupled to the voltage ramp generator, a second input, and an output for pulse-width modulated cycles to be provided to the multi-level converter cell; and
a duty cycle level shifter circuit coupled to the compensation signal output of the error amplifier.

16. The voltage mode control system of claim 15, wherein the duty cycle level shifter circuit is configured to selectively modify the compensation signal to ensure that an average voltage at a node of the multi-level converter cell during a transition into or out of a dead zone of operation essentially matches an average voltage of an adjacent zone just before the transition.

17. The voltage mode control system of claim 15, wherein the duty cycle level shifter circuit is configured to detect a current zone of operation and to provide a modified compensation signal to the second input of the comparator that alternates duty cycles of pairs of adjacent PWM cycles within a dead zone of operation of the multi-level converter cell to achieve a smooth transition sequence from a first zone of operation into the dead zone of operation and from the dead zone of operation to a second zone of operation.

18. The voltage mode control system of claim 17, wherein a first cycle of the pair of adjacent PWM cycles has a 2-state duty cycle with an upper voltage that increases in duration during the transition sequence, and a second cycle of the pair of adjacent PWM cycles has a 2-state inverse duty cycle with a lower voltage that decreases in duration during the transition sequence.

19. The voltage mode control system of claim 17, wherein a first cycle of the pair of adjacent PWM cycles has a 2-state leading duty cycle with an upper voltage that increases in duration during the transition sequence, and a second cycle of the pair of adjacent PWM cycles has a 2-state trailing duty cycle with a lower voltage that decreases in duration during the transition sequence.

20. The voltage mode control system of claim 17, further including a flag circuit coupled to the ramped voltage signal and configured to output to the duty cycle level shifter circuit a dead zone flag signal at one-half of the selected frequency of the ramped voltage signal, wherein the flag circuit includes:
a delay circuit coupled to the ramped voltage signal and configured to output a delayed version of the ramped voltage signal; and
a toggle-type flip-flop coupled to the delayed version of the ramped voltage signal and configured to output a dead zone flag signal at one-half of the selected frequency of the ramped voltage.

21. The voltage mode control system of claim 15, wherein a delay circuit coupled to the ramped voltage signal and configured to output a delayed version of the ramped voltage signal;
a toggle-type flip-flop coupled to the delayed version of the ramped voltage signal and configured to output a dead zone flag signal at one-half of the selected frequency of the ramped voltage signal; a compensation circuit coupled to the output of the error amplifier; and
wherein the duty cycle level shifter circuit further includes:
a first analog comparator having a first input coupled to the compensation signal output, a second input coupled to a first reference voltage source, and an output representing a first flag signal;
a second analog comparator having a first input coupled to the compensation signal output, a second input coupled to a second reference voltage source, and an output representing a second flag signal;
a first AND gate having an inverting input coupled to the first flag signal, a non-inverting input coupled to the second flag signal, and an output;
a first multiplexer having a selection input coupled to the output of the first AND gate, a first input coupled to a reference voltage, a second input coupled to a first adjustment voltage, and an output;
a second AND gate having a non-inverting input coupled to the first flag signal, a non-inverting input coupled to the second flag signal, a non-inverting input coupled to the dead zone flag signal, and an output;
a second multiplexer having a selection input coupled to the output of the second AND gate, a first input coupled to the reference voltage, a second input coupled to a second adjustment voltage, and an output;
a third AND gate having a non-inverting input coupled to the first flag signal, a non-inverting input coupled to the second flag signal, an inverting input coupled to the dead zone flag signal, and an output;
a third multiplexer having a selection input coupled to the output of the third AND gate, a first input coupled to the reference voltage, a second input coupled to a modified third adjustment voltage, and an output;
a first summing circuit having a positive input coupled to the compensation signal output, a negative input coupled to a third adjustment voltage, and an output representing the modified third adjustment voltage as the difference between the compensation signal output and the third adjustment voltage; and
a second summing circuit having a first positive input coupled to the compensation signal output, a second positive input coupled to the output of the third multiplexer, a first negative input coupled to the output of the second multiplexer, a second negative input coupled to the output of the first multiplexer, and an output configured to provide a shifted compensation signal output to the second input of the comparator.

22. A method of smoothly transitioning from a first zone of operation of a pulse-width modulated (PWM) generator to a second zone of operation of the PWM generator through a dead zone of operation, including:
generating in the dead zone of operation a first PWM cycle having a 2-state duty cycle;
generating in the dead zone of operation a second PWM cycle having an inverse 2-state duty cycle; and
modifying the 2-state duty cycle and the inverse 2-state duty cycle while transitioning through the dead zone of operation to increase the 2-state duty cycle and decrease the inverse 2-state duty cycle.

23. The method of claim 22, wherein on transitioning from the first zone of operation to the dead zone of operation, the 2-state duty cycle and the inverse 2-state duty cycle provide a first average voltage approximately equal to a last average voltage of the first zone of operation; and
wherein on transitioning from the dead zone of operation to the second zone of operation, the 2-state duty cycle and the inverse 2-state duty cycle provide a second average voltage approximately equal to a first average voltage of the second zone of operation.

24. The method of claim 22, wherein the pulse-width modulated (PWM) generator is for a multi-level converter, and generating PWM cycles within the first zone of operation having a first duty cycle that generates a final average zone voltage within the multi-level converter at the time of transitioning from the first zone of operation to the dead zone of operation;
wherein on transitioning from the first zone of operation to the dead zone of operation, the 2-state duty cycle and the inverse 2-state duty cycle provide an initial average voltage approximately equal to the final average zone voltage; and
wherein on transitioning from the dead zone of operation to the second zone of operation, the 2-state duty cycle and the inverse 2-state duty cycle provide a final average voltage approximately equal to an initial average zone voltage of the second zone of operation.
